(19) United States
(12) Patent Application Publication
(10) Pub. No.: US 2004/0093175 A1
(43) Pub. Date: May 13, 2004

(54) Forecasting group demand

(76) Inventor: William Henry Tan, Austin, TX (US)

Correspondence Address: FOLEY & LARDNER, 321 NORTH CLARK STREET, SUITE 2800, CHICAGO, IL, 60610-4764, US

(21) Appl. No.: 10/312,076

(22) PCT Filed: Jun. 19, 2001
(86) PCT No.: PCT/SG01/00123

(30) Foreign Application Priority Data
Jun. 19, 2000 (AU) PQ 8203
Jul. 4, 2000 (AU) 43838/00

(51) Int. Cl. G06F 19/00; G01R 21/00; G01R 21/06

(52) U.S. Cl. 702/61; 705/26; 705/28

(57) ABSTRACT

The demand for a particular commodity (e.g. electricity) for a group of consumers is forecast uring measured data about the current consumption of the commodity by individual consumers as well as personal forecasts by the individual consumers as to what they think their future requirements of the commodity will be. The current consumption data, as well as the personal forecasts, are transmitted to a database via a computer network such as the Internet. The data and forecasts are then used to calculate the future demand of the commodity for a group of consumers. Thus, any one-off event or abnormal increase is catered for in calculating the future demand. The forecast demand is used by commodity traders, vendors, resellers, etc to decide how much of the commodity they need to purchase to satisfy their customers' demand. Personal forecasts can be entered by any time, thereby allowing the forecast demand to be updated constantly.

### FIELD OF THE INVENTION

This invention relates to a method and system for forecasting group demand. It relates particularly but not exclusively to a method and system for forecasting the demand by a group of users for a commodity using a computer network and computer software.

### BACKGROUND OF THE INVENTION

It is often necessary for commodity suppliers or resellers to be able to predict future demand for the commodity which they supply If the supplier knows in advance how much of the commodity is required on any given day, the supplier can produce or purchase exactly the right amount of the commodity, resulting in reduced wastage, greater efficiencies in production, and reduced overheads.

Commodity traders in general are not able to bid for the exact amount of commodity resources needed by the traders customers because it is not possible for a trader to be aware of all factors which may affect the customers' future individual requirements for the commodity.

At present, suppliers, resellers and traders typically rely on historical data to provide a forecast of future demand. For example, if the commodity it electricity historical data for a particular group of consumers may indicate a seasonal increase in demand during winter. Historical data may also indicate a trend of a 5% increase per year in the usage of electricity by the group of consumers. Weather forecasts may indicate that the next winter is expected to be especially cold. Accordingly, the predicted demand amongst the group of consumers for electricity during the next winter will be the actual amount required last year, adjusted upwards by 5% to allow for the long-term trend, and adjusted upwards by a further amount to allow for increased demand attributable to the expected cold weather.

However, the supplier, reseller or trader cannot simply purchase or produce the exact amount of the commodity required to satisfy the predicted demand. In order to guard against the adverse consequences which arise if there is insufficient stock to meet demand, it is usually necessary to buy or produce enough of the commodity to provide a margin for error in case levels of demand exceed the forecasted levels.

Variations In demand can happen for a number of reasons. In the case of electricity supply to a group of consumers, the demand may be increase significantly if, for example, one member of the group operates a factory which consumes a lot of electricity, and the factory changes from a one-shift operation to a threeshift operation. Alternatively, demand may decrease significantly if some of the consumers replace electrical appliances with gas appliances.

Statistical analysis can be applied to fluctuations in demand over a period of time, and an appropriate safety level of commodity stock can be determined. However, statistical analysis does not cater for significant changes in demand brought about by one-off events, and a statistically-determined safety margin is still a relatively large one, resulting in considerable wastage of the commodity, and significant overhead costs to the supplier, reseller or trader.

An object of the present invention is to provide an improved method of forecasting demand.

### Summary of the Invention

According to a first aspect of the invention, there is provided a method of forecasting the demand by a group of users for a commodity, including the following steps:

(a) consumption data relating to consumption of the commodity by individual users is measured;

(b) the measured consumption data Is stored in a computer database;

(c) individual users enter personal forecasts for requirements of the commodity using computers or other digital communications apparatus;

(d) the personal forecasts are transmitted to the computer database via a computer network;

(e) forecasts of demand for the group are calculated based on the measured consumption data and the personal forecasts.

The consumption data may be measured in any suitable manner. In less sophisticated cases, the consumption data may be measured by measuring the amount of the commodity leaving the supplier's premises. In more sophisticated cases, consumption data is gathered by measuring the amount of the commodity supplied to individual consumers or groups of consumers or resellers. In an especially preferred case, the measured consumption data is measured by meters or sensors associated with individual users, and the data measured by the meters or sensors is transmitted to the computer database via the computer network.

The computer database may be any suitable database using any suitable database software. The database may reside solely on one computer, or it may be distributed over two or more computers. Parts of the database may reside on individual users' computers, with other parts residing on database server.

Individual users may enter personal forecasts for requirements of the commodity in any suitable manner. In preferred arrangements, software operating on the user's computer presents the user with a form or template for entering and then posting the appropriate details. In an especially preferred arrangement individual users are presented with personal consumption profiles based on measured consumption data relating to them, and they are requested to enter a personal forecast if they anticipate that their requirements for the commodity will deviate from their measured personal consumption profile.

Individual users may use any suitable computers or digital communications apparatus for entering personal forecasts for requirements of the commodity. Suitable digital communications apparatus include Personal Digital Assistants such as PalmPilots™, mobile telephones, Wireless Application Protocol-enabled devices, and Web-enabled televisions.

The computer network may be any suitable computer network. It may be a local area network or, more preferably, a wide area network. More preferably still, the computer network is the Internet and the database operates on an Internet database server.

The forecasts of demand for the group may be calculated in any suitable way, based on tee measured consumption data and the personal forecasts. Preferably, demand forecasts are generated automatically by a computer according to a pre-programmed algorithm.

The method of the present invention is particularly useful to commodities traders. In a preferred forms the inventive method includes the further step of using the forecasts of demand for the group as a basis for predicting future needs for a commodity for the purpose of bidding for the commodity in a commodities exchange.

The commodity to which the inventive method relates may be any suitable commodity or commodities. In one embodiment of the invention, the commodity is a non-tangible commodity such as electricity, oil, gas, or communications bandwidth. In another embodiment of the invention, the commodity is a tangible commodity such as a type of food or a type of raw materials, In yet another embodiment of the invention, the commodity is a service such as a transportation service or a financial service.

It will be seen that the invention has applicability to a very broad range of different types of commodities. A single forecasting server located on the Internet can be used for forecasting the needs of groups of individuals for a number of different types of commodities.

According to a second aspect of the present invention, there is provided a system for forecasting the demand by a group of users for a commodity, including:

(a) measuring apparatus, for measuring data relating to consumption of the commodity by individual users;

(b) a computer database, for storing the consumption data;

(c) computers or other digital communications apparatus associated with individual users, allowing individual users to enter personal forecasts for requirements of the, commodity;

(d) a computer network, linking the computers or other digital communications apparatus associated with individual users to the database; and

(e) group forecasting computer software for calculating forecasts of demand for the group based on the measured consumption data and the personal forecasts.

The measuring apparatus may be any suitable type of measuring apparatus. The suitability of the measuring apparatus depends upon the particular commodity being measured. The measuring apparatus may be located at the premises of the supplier, or at the premises of individual users or groups of users. In a preferred arrangement, the measuring apparatus consists of or includes meters or sensors associated with individual users.

The computer database may be any suitable database using any suitable database software. The database may reside solely on one computer, or it may be distributed over two or more computers. Parts of the database may reside on individual users' computers, with other parts residing on database server.

The computers or other digital communications apparatus associated with individual users may be of any suitable type. Suitable digital communications apparatus include Personal Digital Assistants such as PalmPilot™, mobile telephones, Wireless Application Protocol-enabled devices, and Web-enabled televisions.

The computer network may be any suitable computer network it may be a local area network or, more preferably, a wide area network. More preferably still, the computer network Is the Internet, and the database operates on an Internet database server.

Preferably the system further includes user computer software running on computers or other digital communications apparatus associated with individual users, with forms or templates being displayed to users by the software, enabling the users to enter and then post the appropriate details for personal forecasts. It is further preferred that individual users are presented with personal consumption profiles based on measured consumption data relating to them, the user software enabling individual users to enter a personal forecast if they anticipate that their requirements for the commodity will deviate from their measured personal consumption profile.

By accumulating together the personal forecasts of a number of members of the group of users, the system of the present invention allows a supplier, reseller or trader to obtain a group forecast which is considerably more accurate than could be provided by considering historical data alone. Because of the extensive amount of data collection and comparison necessary to create a combined forecast from a compilation of individual forecasts, it would not have been economically feasible to use the method of the present invention on a large scale without the use of computers.

In a preferred arrangement, the inventive system further includes a communications link to a commodity trader, enabling the commodity trader to use the forecasts of demand for the group as a basis for predicting future needs for a commodity for the purpose of bidding for the commodity in a commodities exchange.

### BRIEF DESCRIPTION OF THE DRAWINGS

The invention will hereinafter be described In greater detail by reference to the attached drawings which show an example form of the invention. It is to be understood that the particularity of the drawings does not supersede the generality of the preceding description of the invention.

FIG. 1 is a schematic diagram illustrating one the arrangement of components according to one embodiment of the present invention.

FIG. 2 Is a chart showing a personal consumption profile for average consumption of a commodity by the user throughout a day.

FIG. 3 is a chart showing a consumption profile for measured consumption of a commodity by an Individual or group of users over a period of time,

FIG. 4 is a flow diagram showing the steps involved in an embodiment of the inventive method.

### DETAILED DESCRIPTION

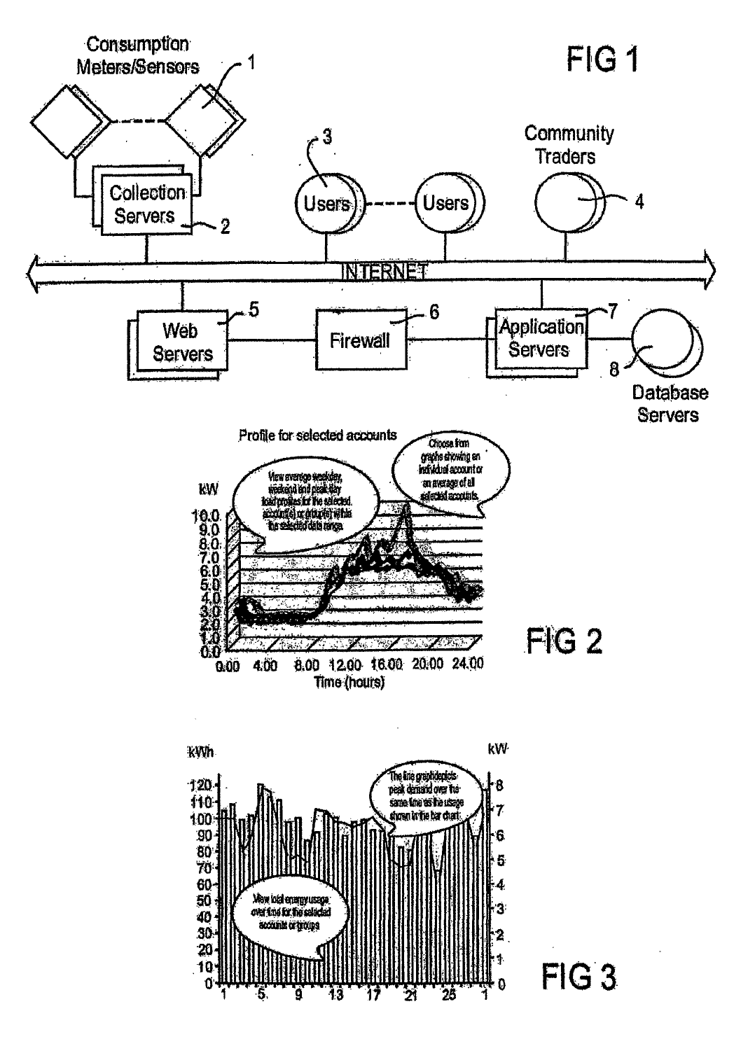

Referring firstly to FIG. 1, there is shown a system for forecasting the demand by a group of users for a commodity according to an embodiment of the invention. The system includes measuring apparatus 1, for measuring data relating to consumption of the commodity by individual users. Database servers 8 are for storing the consumption data. Computers or other digital communications apparatus 3 are associated wtto individual users, allowing individual users to enter personal forecasts for requirements of the commodity. A computer network, in this case the Internet, links the computers or other digital communications apparatus 3 associated with individual users to the database servers 8. Group forecasting computer software calculates forecasts of demand for the group based on the measured consumption data and the personal forecasts.

The Internet can be TCP/IP Socket or Broadband based. Security for the whole infrastructure can be Implemented using standard Internet solutions such as HTTPS or SSL protocol,

In the particular embodiment illustrated In FIG. 1, real time user consumption data is collected by meters/sensors 1, and accumulated by collection servers 2. Measured data is forwarded to application servers 7 over the Internet.

Users log onto web servers 5 from their computers or other digital communications devices 3. Web servers 5 serve to the users pages which allow them to inspect their personal consumption profiles, which are based on the data measured by meters/sensors 1 and accumulated by collection servers 3. If a user anticipates a change in consumption, web servers 5 allow the user to enter details of the anticipated change in the users personal demand. The data so collected directly from the user is posted to application servers 7 through firewall 6 (which protects against unauthorised access to application servers 7 and database servers 8). Data is stored permanently in database servers 8.

Applicaton servers 7 calculate individual user profiles based on measured data, and also group demand forecasts based on an aggregate of individual user forecasts. Commodity traders 4 can view the group demand forecasts on web servers 5.

FIG. 2 shows an example of a measured daily average profile for an individual user. The commodity in this particular example is electricity. Details of the actual information and graphical display will, or course, vary depending upon the commodity type. The information is displayed in a web browser or other device for displaying information sent across the Internet such as a Personal Digital Assistant, WebTV, or WAP-enabled mobile phone.

FIG. 3 shows another measured profile for a user. This particular display shows the total amount of electricity consumed for each day in a month, and the peak demand over the same time.

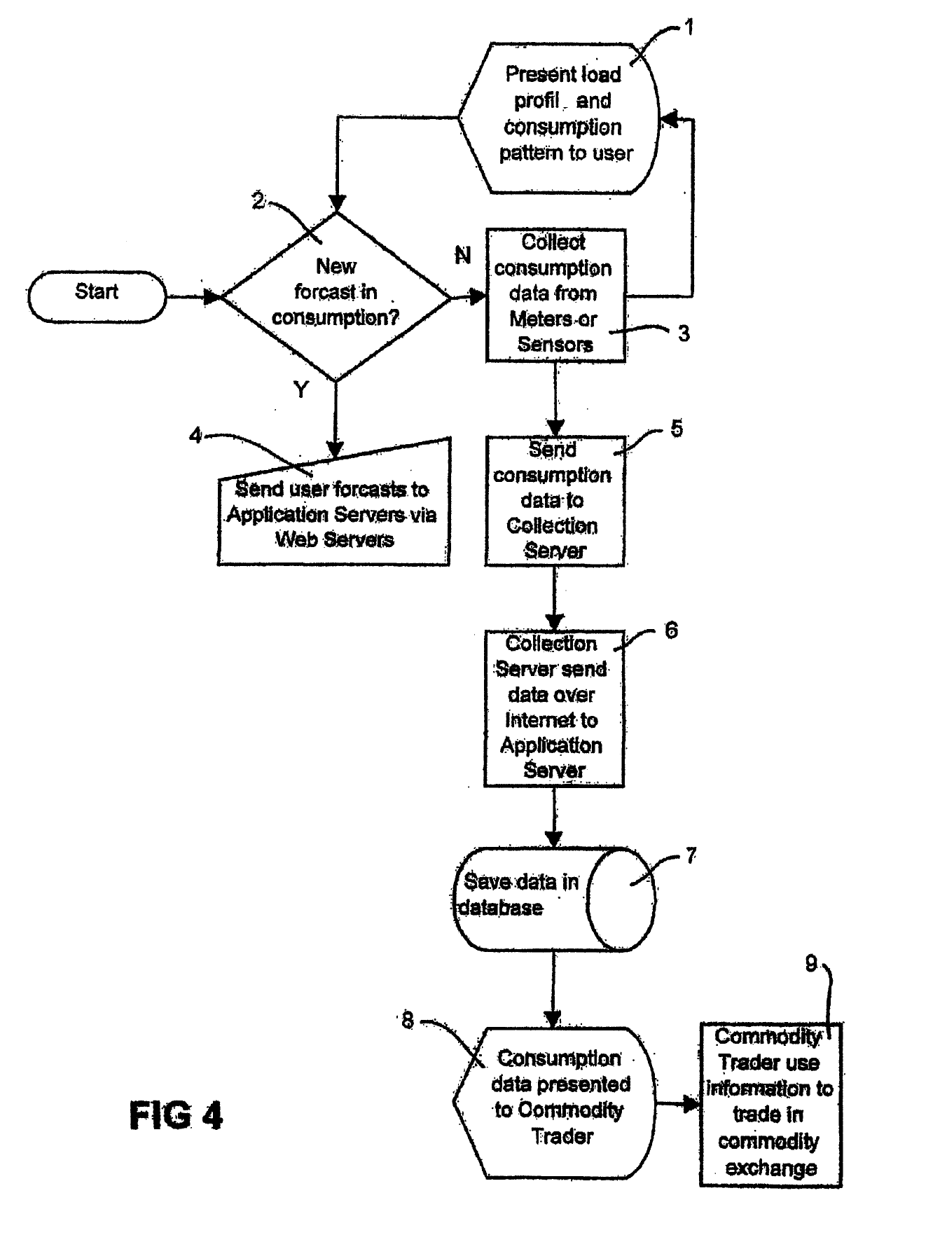

FIG. 4 shows a flow chart illustrating the steps involved in an embodiment of the inventive method. These steps are:

1. A user load profile and consumption pattern is displayed to the user in a web browser (or other display device).

2. The user views the load profile and decides whether a change in the forecast of demand for future supplies of the commodity is needed.

3. If there is no change in the forecast, the consumption meters and sensors continue to collect consumption information.

4. If there is a change in the forecast, the new forecast is fed to the Application server via the Web server.

5. The collection server collects data from the consumption meters/sensors.

6. The collection server, after making a local copy of the data, sends the data to the application server over the Internet.

7. The application server saves a local copy of the data into the database server.

8. The application server collates, validates and presents the data as meaningful information for display.

9. A commodity trader uses the real-time information provided by the system for bidding for the correct amount of the commodity needed by the users. Although a margin for safety in estimated demand may still be required, the method of the present invention substantially reduces the size of the required margin.

It will be seen that the advatages provided by the preferred embodiment of the invention include the following:

1. The commodity trader is provided with accurate real-time data Indicating the amounts of commodities required by the users which the trader represents.

2. This places the commodity trader in a sounder bargaining position.

3. Users are given detailed feedback concerning their own consumption patterns, allowing them to forecast more precisely their own requirements.

It is to be understood that various alterations, additions and/or modifications may be made to the parts previously described without departing from the ambit of the present invention.

1. A method of forecasting the demand by a group of users for a commodity, including the following steps:
(a) consumption data relating to consumption of the commodity by individual users is measured;
(b) the measured consumption data is stored in a computer database;
(c) individual users enter personal forecasts for requirements of the commodity using computers or other digital communications apparatus;
(d) the personal forecasts are transmitted to the computer database via a computer network;
(e) forecasts of demand for the group are calculated based on the measured consumption data and the personal forecasts.

2. A method according to claim 1 wherein the measured consumption data is measured by meters or sensors associated with individual users, and the data measured by the meters or sensors is transmitted to the computer database via the computer network.

3. A method according to claim 1 or claim 2 wherein the computer network is the Internet, and the database operates on an Internet database server.

4. A method according to any one of claims 1 to 3 wherein individual users are presented with personal consumption profiles based on measured consumption data relating to them, and they are requested to enter a personal forecast if they anticipate that their requirements for the commodity will deviate from their measured personal consumption profile.

5. A method according to any one of claims 1 to 4 including the further step of using the forecasts of demand for the group as a basis for predicting future needs for a commodity for the purpose of bidding for the commodity in a commodities exchange.

6. A method according to any one of claims 1 to 5 wherein the commodity is a non-tangible commodity such as electricity, oil, gas, or communications bandwidth.

7. A method according to any one of claims 1 to 5 wherein the commodity is a tangible commodity such as a type of food or a type of raw materials.

8. A method according to any one of claims 1 to 5 wherein the commodity is a service such as a transportation service or a financial service.

9. A system for forecasting the demand by a group of users for a commodity, including:
(a) measuring apparatus, for measuring data relating to consumption of the commodity by individual users;
(b) a computer database, for storing the consumption data;
(c) computers or other digital communications apparatus associated with individual users, allowing individual users to enter personal forecasts for requirements of the commodity;
(d) a computer network, linking the computers or other digital communications apparatus associated with individual users to the database; and
(e) group forecasting computer software for calculating forecasts of demand for the group based on the measured consumption data and the personal forecasts.

10. A system according to claim 9 wherein the measuring apparatus consists of or includes meters or sensors associated with individual users.

11. A system according to claim 9 or claim 10 wherein the computer network Is the Internet, and the database operates on an Internet database server.

12. A system according to any one of claims 9 to 11 further including user computer software running on computers or other digital communications apparatus associated with individual users, whereby individual users are presented with personal consumption profiles based on measured consumption data relating to them, the user software enabling individual users to enter a personal forecast if they anticipate that their requirements for the commodity will deviate from their measured personal consumption profile.

13. A system according to any one of claims 9 to 12 further including a communications link to a commodity trader, enabling the commodity trader to use the forecasts of demand for the group as a basis for predicting future needs for a commodity for the purpose of bidding for the commodity in a commodities exchange.

14. A method of forecasting the demand by a group of users for a commodity substantially as hereinbefore described with reference to the drawings.

15. A system for forecasting the demand by a group of users for a commodity substantially as hereinbefore described with reference to the drawings.
